(19) United States
(12) Patent Application Publication
(10) Pub. No.: US 2025/0054559 A1
(43) Pub. Date: Feb. 13, 2025

(54) SEMICONDUCTOR STORAGE DEVICE AND METHOD

(71) Applicant: SONY SEMICONDUCTOR SOLUTIONS CORPORATION, KANAGAWA (JP)

(72) Inventors: GAKU SHIMADA, KANAGAWA (JP); ATSUSHI TAMURA, KANAGAWA (JP)

(21) Appl. No.: 18/718,810

(22) PCT Filed: Dec. 2, 2022
(86) PCT No.: PCT/JP2022/044504

§ 371 Date: Jun. 12, 2024

(30) Foreign Application Priority Data
Dec. 20, 2021 (JP) 2021-205789

(51) Int. Cl. G11C 29/44

(52) U.S. Cl. CPC G11C 29/44

(57) ABSTRACT

A semiconductor storage device (100) includes a normal cell array (11a) including a plurality of normal cells (11), each of the plurality of normal cells being a non-volatile memory cell; and a plurality of dummy cells (12) arranged in at least a partial region of an outer peripheral region of the normal cell array (11a), each of the plurality of dummy cells being a non-volatile memory cell. Information on the semiconductor storage device (100) is written in at least some dummy cell (12) of the plurality of dummy cells (12).

### FIELD

The present disclosure relates to a semiconductor storage device and a method.

### BACKGROUND

For example, Patent Literature 1 discloses a semiconductor storage device that writes information in a programmable ROM (PROM) or a one-time programmable ROM (OPT) provided separately from a magnetoresistive memory cell array.

### CITATION LIST

### Patent Literature

Patent Literature 1: JP 2010-225259 A

### SUMMARY

### Technical Problem

Providing a non-volatile memory region such as a PROM or an OPT separately from a memory cell array causes the chip layout area to increase and the area efficiency of the semiconductor storage device to decrease.

One aspect of the present disclosure provides a semiconductor storage device and a method capable of suppressing a decrease in area efficiency.

### Solution to Problem

A semiconductor storage device, according to one aspect of the present disclosure, includes: a normal cell array including a plurality of normal cells, each of the plurality of normal cells being a non-volatile memory cell; and a plurality of dummy cells arranged in at least a partial region of an outer peripheral region of the normal cell array, each of the plurality of dummy cells being a non-volatile memory cell, wherein information on the semiconductor storage device is written in at least some dummy cell of the plurality of dummy cells.

A method, according to one aspect of the present disclosure, is a method for using a semiconductor storage device, the semiconductor storage device including: a normal cell array including a plurality of normal cells, each of the plurality of normal cells being a non-volatile memory cell; and a plurality of dummy cells arranged in at least a partial region of an outer peripheral region of the normal cell array, each of the plurality of dummy cells being a non-volatile memory cell, the method includes writing information on the semiconductor storage device in at least some dummy cell of the plurality of dummy cells.

### BRIEF DESCRIPTION OF DRAWINGS

FIG. 1 is a diagram depicting an example of a schematic configuration of a semiconductor storage device 100 according to an embodiment.

FIG. 2 is a diagram depicting an example of a schematic configuration of a normal cell 11.

FIG. 3 is a diagram depicting an example of a schematic configuration of a dummy cell 12.

FIG. 4 is a diagram depicting an example of a first connection form of a dummy cell port 3 and the dummy cell 12.

FIG. 5 is a diagram depicting an example of a second connection form of the dummy cell port 3 and the dummy cell 12.

FIG. 6 is a diagram depicting an example of a third connection form of the dummy cell port 3 and the dummy cell 12.

FIG. 7 is a diagram depicting an example of writing information to the dummy cell 12.

FIG. 8 is a flowchart depicting an example of a shipment test (a method for using the semiconductor storage device 100).

FIG. 9 is a diagram depicting an example of a subsequent defective cell 11NGL.

FIG. 10 is a flowchart depicting an example of returned product analysis (a method for using the semiconductor storage device 100).

### DESCRIPTION OF EMBODIMENTS

Hereinafter, embodiments of the present disclosure will be described in detail with reference to the drawings. In each of the following embodiments, the same elements are denoted by the same reference signs, and repetitive description will be omitted.

The present disclosure will be described according to the following item order.
0. Introduction
1. Embodiment
2. Modification
3. Example of Effects

### 0. Introduction

In a semiconductor storage device, various types of information are stored (held, contained) and utilized over a long period of time. For example, in Patent Literature 1, information of setting data of an internal operation state is contained in a PROM or an OPT provided in a region different from a memory cell array that is normally used. Providing a non-volatile memory region such as a PROM or an OPT separately from a memory cell array causes the chip layout to increase accordingly and the area efficiency of the semiconductor storage device to decrease.

Some semiconductor storage devices can be used with a defect in some memory cells by using an error correcting code (ECC). It is desirable to make it possible to distinguish between a defective memory cell that exists from the beginning and a defective memory cell that is generated subsequently. For example, it is conceivable to store information on a defective memory cell in a semiconductor storage device at the time of a shipment test or the like. However, a large non-volatile memory region is required to record information on defective memory cells that may exist numberlessly. A problem of decrease in area efficiency becomes apparent.

The technology to be disclosed suppresses a decrease in area efficiency. For example, it is possible to store information for a long period of time while suppressing an increase in chip layout.

### 1. Embodiment

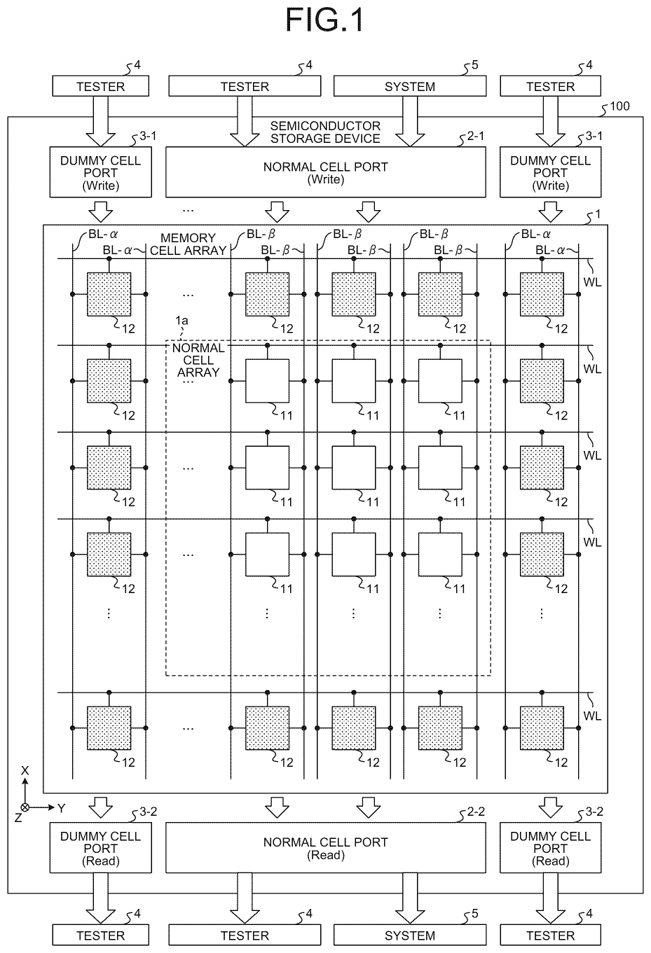

FIG. 1 is a diagram depicting an example of a schematic configuration of a semiconductor storage device 100 according to an embodiment. The semiconductor storage device 100 is mounted on, for example, an electronic device or the like, and is used as a storage device. The semiconductor storage device 100 includes a semiconductor chip. In the example depicted in FIG. 1, the semiconductor storage device 100 includes a memory cell array 1, a normal cell port 2, and a dummy cell port 3. In the drawing, an XYZ coordinate system for the memory cell array 1 is illustrated. The X-axis direction corresponds to a column direction of the memory cell array 1, and the Y-axis direction corresponds to a row direction of the memory cell array 1. The X-axis direction may also be referred to as a vertical direction, a bit line (corresponding to a bit line BL to be described later) direction, or the like. The Y-axis direction may also be referred to as a horizontal direction, a word line (corresponding to a word line WL to be described later) direction, or the like.

The memory cell array 1 includes a plurality of normal cells 11 and a plurality of dummy cells 12. Each of the plurality of normal cells 11 is a non-volatile memory cell and is arranged in an array. An array including a plurality of normal cells 11 is referred to as a normal cell array 1a and illustrated in the drawing. Each of the plurality of dummy cells 12 is also a non-volatile memory and is arranged in an outer peripheral region of the normal cell array 1a. The dummy cell 12 is illustrated with hatching so that the normal cell 11 and the dummy cell 12 can be easily distinguished.

The normal cell 11 is a memory cell in which information is read and written when the semiconductor storage device 100 is mounted on an electronic device or the like and used as a storage device. The dummy cell 12 is a memory cell in which information is not read or written when the semiconductor storage device 100 is mounted on an electronic device or the like and used as a storage device. The dummy cell 12 is disposed in a region closer to an edge of the memory cell array 1 than the normal cell 11. Conventionally, information is not read from or written to the dummy cell 12, and methods for accessing the dummy cell 12 are not provided. In the semiconductor storage device 100 according to the embodiment, the dummy cell 12 can be accessed as described later.

The normal cell 11 and the dummy cell 12 are connected to a corresponding word line WL and a pair of bit lines BL. In this example, the word line WL extends in the row direction (Y-axis direction), and the bit line BL extends in the column direction (X-axis direction). One word line WL is commonly connected to the normal cell 11 and the dummy cell 12 in the same row. One bit line BL is commonly connected to the normal cell 11 and the dummy cell 12 in the same column, or is commonly connected to the dummy cells 12 in the same column. One bit line BL of the pair of bit lines BL is also referred to as a sense line or the like.

The bit line BL of the dummy cell 12 arranged in a region outside the normal cell array 1a in the array row direction (Y-axis direction) is referred to as a bit line BL-a and illustrated in the drawing. The bit line BL of the dummy cell 12 arranged in a region outside the normal cell array 1a in the array column direction (X-axis direction) is referred to as a bit line BL-B and illustrated in the drawing.

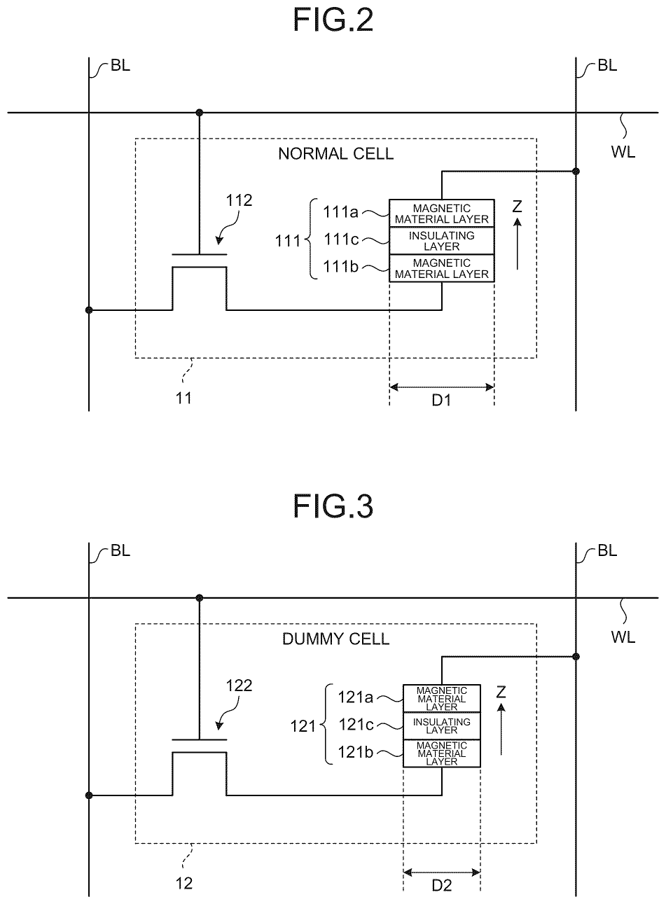

FIG. 2 is a diagram depicting an example of a schematic configuration of the normal cell 11. The normal cell 11 includes a magnetic memory element 111 and a selection transistor 112. The magnetic memory element 111 is an example of a non-volatile memory element. The magnetic memory element 111 exemplified in FIG. 2 is a magnetoresistive random access memory (MRAM) element.

The magnetic memory element 111 includes a magnetic material layer 111a, a magnetic material layer 111b, and an insulating layer 111c. In the example depicted in FIG. 2, the stacking direction is the Z-axis direction.

The magnetic material layer 11a and the magnetic material layer 111b include a ferromagnetic material. One of the magnetic material layer 111a and the magnetic material layer 111b is a fixed layer having a fixed magnetization direction (direction of magnetic moment), and is also referred to as a reference layer or the like. The other of the magnetic material layer 111a and the magnetic material layer 111b is a layer capable of changing (inverting) the magnetization direction, and is also referred to as a storage layer or the like. Examples of the material of the magnetic material layer 111a and the magnetic material layer 111b includes Fe, Co, Ni, and Mn.

The insulating layer 111c includes a non-magnetic material, and is provided between the magnetic material layers, that is, between the magnetic material layer 111a and the magnetic material layer 111b. The insulating layer 111c is also referred to as a tunnel barrier layer or the like. Examples of the material of the insulating layer 111c include MgO.

A width D1 is exemplified as an index indicating the size of the magnetic memory element 111, more specifically, the size of the magnetic memory element 111 in plan view (as viewed in the Z-axis direction). When the magnetic memory element 111 has a circular shape in plan view, the width D1 corresponds to the diameter of the magnetic memory element 111.

The magnetic memory element 111 and the selection transistor 112 are connected in series between the pair of bit lines BL. In the example depicted in FIG. 2, the selection transistor 112 is a field effect transistor (FET), and the magnetic memory element 111, one of a drain and a source of the selection transistor 112, and the other of the drain and the source of the selection transistor 112 are connected in this order between the pair of bit lines BL. A gate of the selection transistor 112 is connected to the word line WL.

The bit line BL and the word line WL are connected to a power supply circuit (not illustrated) or the like so that a desired current can flow through the magnetic memory element 111. At the time of writing information, a voltage for applying a current to the magnetic memory element 111 is applied via the pair of bit lines BL corresponding to a desired normal cell 11. A voltage is applied to the word line WL corresponding to the desired normal cell 11, that is, the gate of the selection transistor 112, and the selection transistor 112 is turned on (conductive state). A current flows between the bit lines BL, that is, in the magnetic memory element 111, and information is written (stored) through magnetization reversal. At the time of reading information, a voltage is applied to the word line WL corresponding to the desired normal cell 11, and the current flowing between the bit lines BL is detected. The detection of the current corresponds to a detection of the resistance value of the magnetic memory element 111, and information is read through the detection.

FIG. 3 is a diagram depicting an example of a schematic configuration of the dummy cell 12. The dummy cell 12 may be formed to have the same configuration as that of the normal cell 11 (FIG. 2). The non-volatile memory element and the selection transistor of the dummy cell 12 are referred to as a magnetic memory element 121 and a selection transistor 122, respectively, and illustrated in the drawing. The magnetic material layers and the insulating layer of the magnetic memory element 121 are referred to as a magnetic material layer 121a, a magnetic material layer 121b, and an insulating layer 121c, respectively, and they are illustrated in the drawing.

The size of the magnetic memory element 121 of the dummy cell 12 may be different from the size of the magnetic memory element 111 of the normal cell 11. Specifically, the magnetic memory element 121 of the dummy cell 12 may be smaller than the magnetic memory element 111 of the normal cell 11. This is because there is a circumstance that the dummy cell 12 is arranged in a region closer to an edge of the memory cell array 1 than the normal cell 11, as described above. In FIG. 3, the width of the magnetic memory element 121 is referred to as a width D2 and illustrated in the drawing. The width D2 of the exemplified magnetic memory element 121 is smaller than the width D1 (FIG. 2) of the magnetic memory element 111.

Writing and reading of information to and from the dummy cell 12 may be performed in the same manner as the writing of information to and from the normal cell 11 described above. That is, a voltage for applying a current to the magnetic memory element 121 is applied via the pair of bit lines BL corresponding to a desired dummy cell 12. At the time of reading information, the current flowing between the bit lines BL, that is, a resistance value is detected.

The state of the dummy cell 12 before information is written is referred to as an initial state. By causing at least some dummy cell 12 to have a state (opposite state) different from the initial state, information is written in the dummy cells 12.

As described above, the magnetic memory element 121 included in the dummy cell 12 may be smaller than the magnetic memory element 111 included in the normal cell 11. As the magnetic memory element 121 becomes smaller, the voltage required for writing information becomes higher, but the written information hardly disappears. Accordingly, information can be held for a long period of time, and reliability of information stored in the dummy cell 12 improves.

Writing information into the dummy cell 12 may include breaking the insulating layer 121c. The initial state in that case is a state in which the resistance value of the magnetic memory element 121 is large. The state different from the initial state is a state in which the resistance value of the magnetic memory element 121 is small. Breaking the magnetic memory element 121 causes the magnetic memory element 121 to have a state different from the initial state. The breakdown of the insulating layer 121c is performed, for example, by flowing a current (overcurrent) larger than a normal current. The breakdown of the insulating layer 121c is also referred to as MgO breakdown or the like when the insulating layer 121c is made of MgO. The magnetic memory element 121 after the breakdown of the insulating layer 121c is fixed in a state where the resistance value is small, and it does not return to the initial state. Information can be held for a further long period of time, and reliability of information stored in the dummy cell 12 further improves.

Returning to FIG. 1, the normal cell port 2 is a port for accessing a plurality of normal cells 11 from the outside of the semiconductor storage device 100. The access includes writing information to the normal cell 11 (Write) and reading information from the normal cell 11 (Read). In FIG. 1, the normal cell port 2 for writing and the normal cell port 2 for reading are illustrated separately as a normal cell port 2-1 and a normal cell port 2-2. The normal cell port 2-1 and the normal cell port 2-2 may be the same port.

FIG. 1 illustrates, as an example, a tester 4 and a system 5 as elements that access the normal cell 11 from the outside of the semiconductor storage device 100 via the normal cell port 2. For example, the tester 4 performs a function test of the semiconductor storage device 100 before shipment and a function test of the semiconductor storage device 100 returned as a defective product after shipment. The system 5 operates on an electronic device or the like on which the semiconductor storage device 100 after shipment is mounted, and uses the semiconductor storage device 100 as a storage device.

The normal cell port 2 may include a terminal, a pad, and the like for enabling electrical connection from the tester 4 or the system 5. The normal cell port 2 may include a circuit and the like for communicating with the tester 4 or the system 5. As schematically indicated by white arrows in FIG. 1, the tester 4 and the system 5 write information to the normal cell 11 via the normal cell port 2-1 and read information from the normal cell 11 via the normal cell port 2-2.

The dummy cell port 3 is a port for accessing at least some dummy cell 12 from the outside of the semiconductor storage device 100. The dummy cell port 3 may be a dedicated port different from the normal cell port 2, the dedicated port being able to directly apply a voltage or a current to the dummy cell 12 or measure the voltage or the current.

The tester 4 is exemplified as an element that accesses the dummy cell 12 from the outside of the semiconductor storage device 100 via the dummy cell port 3. The dummy cell port 3 may include a terminal, a pad, and the like for enabling electrical connection with the tester 4, and may include a circuit and the like for communicating with the tester 4.

In FIG. 1, the dummy cell port 3 for writing and the dummy cell port 3 for reading are illustrated separately as a dummy cell port 3-1 and a dummy cell port 3-2. As schematically indicated by white arrows in FIG. 1, the tester 4 writes information to the dummy cell 12 via the dummy cell port 3-1 and reads information from the dummy cell 12 via the dummy cell port 3-2. The dummy cell port 3-1 and the dummy cell port 3-2 may be the same port.

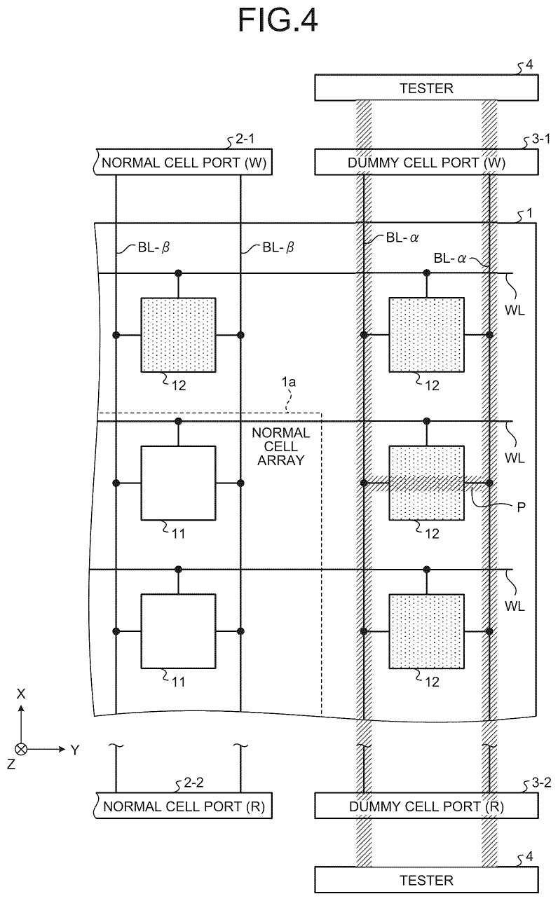

Various connection forms of the dummy cell port 3 and the dummy cell 12 are possible. Some examples are described with reference to FIGS. 4 to 6.

FIG. 4 is a diagram depicting an example of a first connection form of the dummy cell port 3 and the dummy cell 12. The dummy cell port 3 is connected to the bit line BL-x. The dummy cells 12 connected to the bit line BL-x can be accessed. The tester 4 can write information to the dummy cells 12 via the dummy cell port 3-1 and read information from the dummy cells 12 via the dummy cell port 3-2. Information is written to the corresponding dummy cell 12 and information is read from the dummy cell 12 using any access path, for example, an access path P schematically illustrated in the drawing.

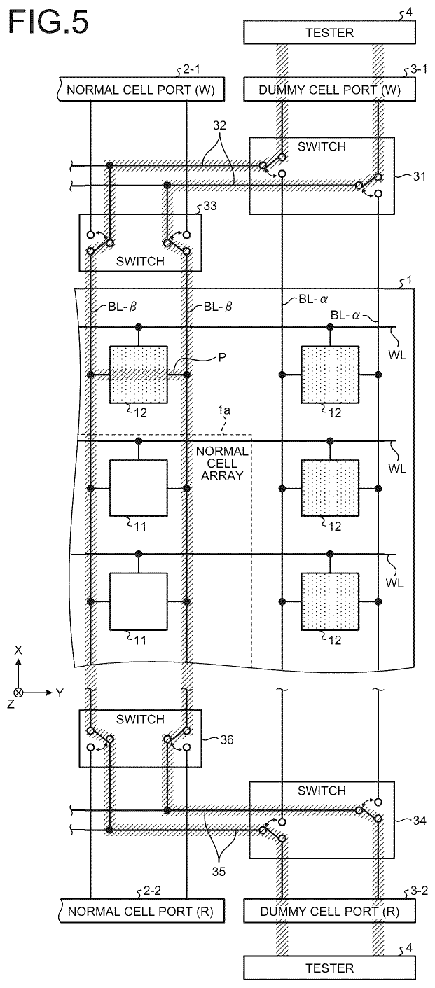

FIG. 5 is a diagram depicting an example of a second connection form of the dummy cell port 3 and the dummy cell 12. The semiconductor storage device 100 includes a switch and a wiring connected between the dummy cell port 3, the bit line BL-a, and the bit line BL-B. The switch connects the dummy cell port 3 to the bit line BL-a or the bit line BL-B. Examples of the switch and the wiring include a switch 31, a wiring 32, a switch 33, a switch 34, a wiring 35, and a switch 36.

The switch 31 is connected between the dummy cell port 3-1, the bit line BL-a, and the wiring 32. The switch 31 switches between a state of connecting the dummy cell port 3-1 and the bit line BL- and a state of connecting the dummy cell port 3-1 and the wiring 32.

The wiring 32 extends in the array row direction (Y-axis direction, word line direction) so as to be connected between the switch 31 and the switch 33 of each column.

The switch 33 is provided for each column of the normal cell array 1a. The switch 33 is connected between the normal cell port 2-1, the bit line BL-B, and the wiring 32. The switch 33 switches between a state of connecting the normal cell port 2-1 and the bit line BL-B and a state of connecting the wiring 32 and the bit line BL-B.

The switch 34 is connected between the dummy cell port 3-2, the bit line BL-a, and the wiring 35. The switch 31 switches between a state of connecting the dummy cell port 3-2 and the bit line BL-x and a state of connecting the dummy cell port 3-2 and the wiring 35.

The wiring 35 extends in the array row direction (Y-axis direction, word line direction) so as to be connected between the switch 34 and the switch 36 of each column.

The switch 36 is provided for each column of the normal cell array 1a. The switch 36 is connected between the normal cell port 2-2, the bit line BL-B, and the wiring 35. The switch 36 switches between a state of connecting the normal cell port 2-2 and the bit line BL-B and a state of connecting the wiring 35 and the bit line BL-B.

Specific configurations of the switch 31, the switch 33, the switch 34, and the switch 36 are not particularly limited, but may include, for example, a three-terminal switch as illustrated in FIG. 5. Switching of each switch may be controlled by the dummy cell port 3 or the normal cell port 2.

According to the connection form illustrated in FIG. 5, not only the dummy cell 12 connected to the bit line BL-x but also the dummy cell 12 connected to the bit line BL-B can be accessed. The tester 4 can write information to the dummy cells 12 via the dummy cell port 3-2 and read information from the dummy cells 12 via the dummy cell port 3-2. Information is written to the corresponding dummy cell 12 and information is read from the dummy cell 12 using any access path, for example, an access path P schematically illustrated in the drawing.

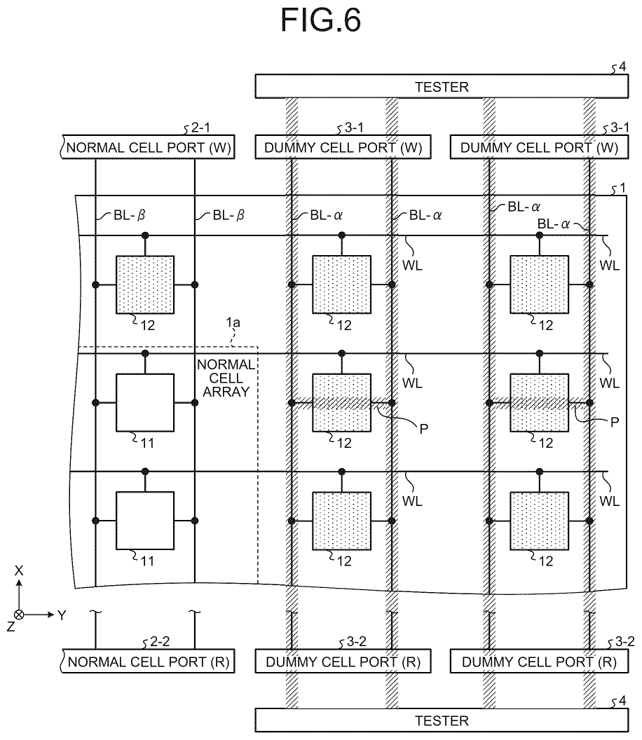

FIG. 6 is a diagram depicting an example of a third connection form of the dummy cell port 3 and the dummy cell 12. The dummy cell port 3 is connected to the bit lines BL-x of the dummy cells 12 arranged over a plurality of columns (two columns in this example) in a region outside the normal cell array 1a in the array row direction (Y-axis direction). A plurality of dummy cell ports 3 are provided in parallel corresponding to the plurality of columns. The tester 4 can write information into the dummy cell 12 in a desired column via the dummy cell port 3-1 and read information from the dummy cell 12 in a desired column via the dummy cell port 3-2. Information is written to the corresponding dummy cell 12 and information is read from the dummy cell 12 using any access path, for example, an access path P schematically illustrated in the drawing.

Of course, a connection form in which the connection form of FIG. 5 (second connection form) and the connection form of FIG. 6 (third connection form) described above are combined is also possible. As more dummy cells 12 become accessible, more information can be written to the dummy cells 12 in detail (finely).

For example, as described above, in the semiconductor storage device 100, the dummy cell 12 can be accessed via the dummy cell port 3. Information on the semiconductor storage device 100 is written in at least some dummy cell 12 of the semiconductor storage device 100. Some examples of the information will be described.

For example, the information may include information on an initial defective cell (among the plurality of normal cells 11) in the normal cell array 1a. The initial defective cell is referred to as an initial defective cell 11NG. The initial defective cell 11NG is a defective cell already existing in the normal cell array 1a at the time of shipment of the semiconductor storage device 100. Examples of the information on the initial defective cell 11NG in the normal cell array 1a include information on the number of the initial defective cells 11NG, information on the address of the initial defective cell 11NG, and information on ECC data. The ECC data is error correcting code data for correcting an error caused by the initial defective cell 11NG in the normal cell array 1a. The information on the number of the initial defective cells 11NG may be bit information corresponding to the number itself, or may be any bit information that can identify the number, unlike the number itself. The same applies to the information on the address of the initial defective cell 11NG, the information on ECC data, and the information on production management described next.

The information written in the normal cell port 2 may include information on production management of the semiconductor storage device 100. Examples of the information on production management include information on a vendor ID, information on a lot number, and information on a chip ID. The vendor ID is identification information for specifying a manufacturer or the like of the semiconductor storage device 100. The lot number is identification information for identifying a manufacturing lot or the like of the semiconductor storage device 100. The chip ID is identification information for identifying an individual or the like of (the semiconductor chip included in) the semiconductor storage device 100.

The dummy cell 12 in which the information is written is arranged in an outer peripheral region of the normal cell array 1a, that is, in the same layout block (in the same memory cell array 1) as the normal cell 11. Writing information in such a dummy cell 12 enables writing of information without providing a non-volatile memory cell region such as a PROM or an OPT separately from the memory cell array 1. Thus, a decrease in area efficiency can be suppressed.

A specific example of writing information to the dummy cell 12 will be described. Hereinafter, a case where the information written to the dummy cell 12 is information on the address of the initial defective cell 11NG will be described as an example.

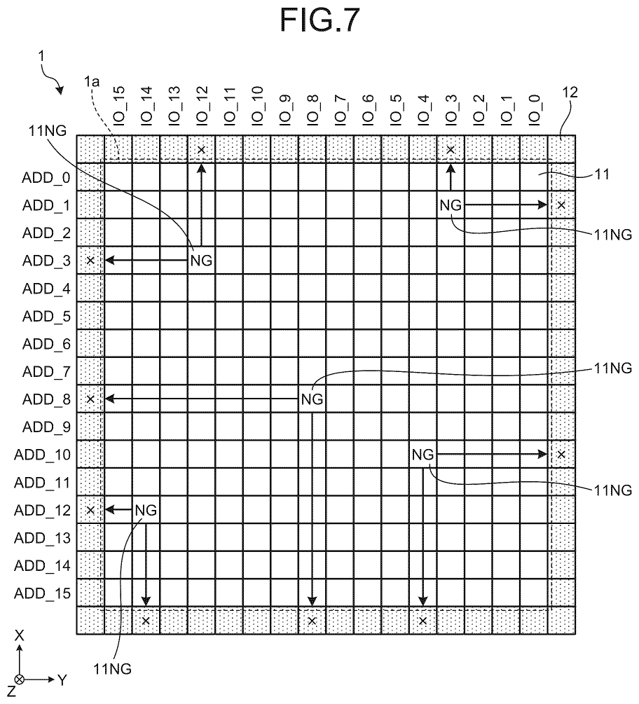

FIG. 7 is a diagram depicting an example of writing information to the dummy cell 12. The memory cell array 1 is exemplified as an array of 16×16 normal cells 11. The address of the normal cell 11 in the array column direction (X-axis direction) is schematically indicated as an address ADD. The address of the normal cell 11 in the array row direction (Y-axis direction) is schematically illustrated as an address IO. The addresses ADD and addresses IO are illustrated as addresses ADD_0 to ADD_15 and addresses IO_0 to IO_15, respectively.

An initial defective cell in the normal cell array 1a is referred to as the initial defective cell 11NG and illustrated in the drawing. In this example, there are five initial defective cells 11NG. Information on these initial defective cells 11NG is written to the dummy cells 12. For example, information on the initial defective cell 11NG is written in the dummy cell 12 arranged at a position corresponding to the initial defective cell 11NG. In FIG. 7, an X mark is attached to the dummy cell 12 in which information is written.

Even when there is the initial defective cell 11NG in the normal cell array 1a, the semiconductor storage device 100 can be shipped as long as it is within a range in which error correction with ECC can be performed. For example, when the number of initial defective cells 11NG existing in one row of the normal cell array 1a is equal to or less than a predetermined number (for example, one or less), error correction can be performed. In the example depicted in FIG. 7, the number of initial defective cells 11NG existing in one row is only 0 or 1, and error correction with ECC data is possible. The semiconductor storage device 100 passes a shipment test and is shipped.

Writing of information into the dummy cell 12 will be further described. In the example depicted in FIG. 7, the information is written by causing the dummy cell 12 in the same row as the initial defective cell 11NG and the dummy cell 12 in the same column as the initial defective cell 11NG to have a state different from the initial state. The combination of these two dummy cells 12 makes it possible to identify the row and column in which the initial defective cell 11NG is located, that is, the address of the initial defective cell 11NG. When information is written to the dummy cell 12 in this manner, only the dummy cells 12 of 16+16=32 bits are (fully) sufficient for the normal cell 11 of 16×16.

If a PROM or an OPT provided in a region different from the memory cell array 1 is used, at least a 9-bit storage region of 4 bits of the address ADD, 4 bits of the address IO, and 1 bit of the EN bit is required to identify one initial defective cell 11NG. When the number of initial defective cells 11NG is N, 9×N bit storage regions are required, and 32 bit dummy cells 12 are not sufficient. When N increases indefinitely, it becomes difficult to cope with such N. The method illustrated in FIG. 7 can deal with such a problem.

The information on the address of the initial defective cell 11NG can be written to the dummy cell 12 in this manner, for example. Of course, the information may be written in the dummy cell 12 in various modes according to the number of accessible dummy cells 12 and the like without being limited to the above example. In addition, information other than the information on the address of the initial defective cell 11NG, for example, the information on the initial defective cell 11NG, the information on production management of the semiconductor storage device 100, and the like described above may be written to the dummy cell 12. For example, the information on ECC data may be written to the corresponding dummy cell 12 (for example, the dummy cell 12 of the same row) for each row of the array.

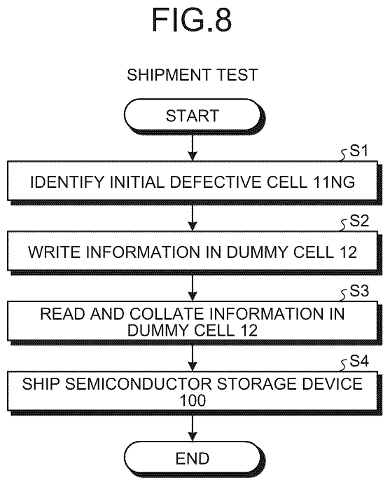

Writing of information into the dummy cell 12 is performed, for example, at the time of a shipment test of the semiconductor storage device 100. In the shipment test to be described next with reference to FIG. 8, information on the initial defective cell 11NG is written to the dummy cell 12.

FIG. 8 is a flowchart depicting an example of the shipment test (a method for using the semiconductor storage device 100).

In Step S1, the initial defective cell 11NG is identified. A function test is performed using the tester 4. The tester 4 accesses a plurality of normal cells 11 in the normal cell array 1a via the normal cell port 2 and identifies the initial defective cell 11NG in the normal cell array 1a. The tester 4 extracts the address ADD and the address IO of the initial defective cell 11NG.

In Step S2, the information is written in the dummy cell 12. The tester 4 accesses the dummy cell 12 via the dummy cell port 3 and checks the initial state of the dummy cell 12. The tester 4 writes information on the initial defective cell 11NG into the dummy cell 12 by causing the dummy cell 12 corresponding to the initial defective cell 11NG identified in Step S1 described above to have a state different from the initial state.

In Step S3, the information in the dummy cell 12 is read and collated. The tester 4 accesses the dummy cell 12 via the dummy cell port 3 and reads information written in the dummy cell 12, in this example, information on the address of the initial defective cell 11NG. The tester 4 collates the information on the address of the initial defective cell 11NG read from the dummy cell 12 with the address ADD and the address IO of the initial defective cell 11NG extracted in Step S1 described above. It is confirmed that both coincide with each other, that is, information is correctly written in the dummy cell 12. In this example, it is assumed that the number of the initial defective cells 11NG existing in one row of the memory cell array 1 is one or less, correction by ECC is possible, and the memory cell array 1 is determined to be a non-defective product.

In Step S4, the semiconductor storage device 100 is shipped. As described above, the semiconductor storage device 100 is shipped in a state in which the information on the initial defective cell 11NG is written in the dummy cell 12.

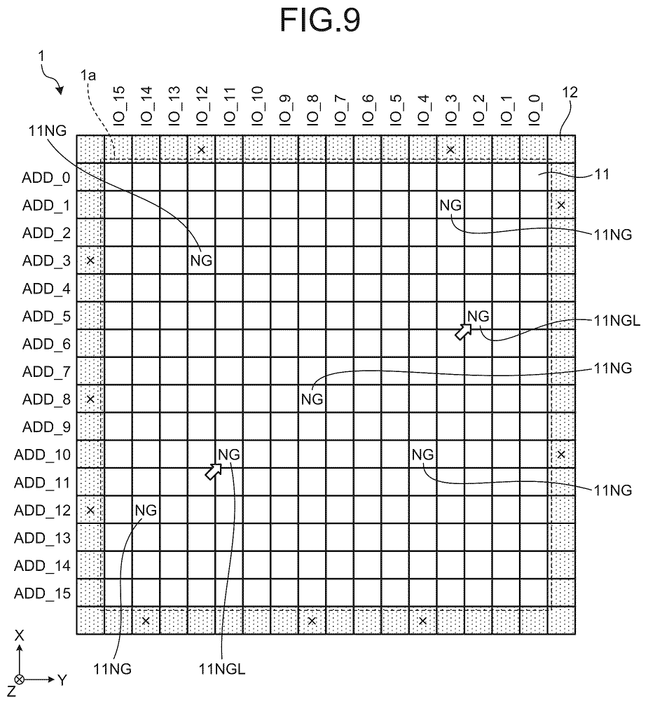

For example, using the semiconductor storage device 100 as described above makes it possible to write information while suppressing a decrease in area efficiency (that is, efficiently write information). The semiconductor storage device 100 after shipment is mounted on, for example, an electronic device or the like and used as a storage device. After shipment, a new initial defective cell 11NG, that is, a subsequent defective cell may be generated in the normal cell array 1a. The subsequent defective cell is referred to as a subsequent defective cell 11NGL. The subsequent defective cell 11NGL will be described with reference to FIG. 9.

FIG. 9 is a diagram depicting an example of the subsequent defective cell NGL. In this example, there are two subsequent defective cells 11NGL indicated by white arrows. In particular, there are two defective cells, the initial defective cell 11NG and the subsequent defective cell 11NGL, in a row of the normal cell array 1a corresponding to the address ADD_10. It is assumed that correction with ECC does not function, and the semiconductor storage device 100 is returned as a defective product.

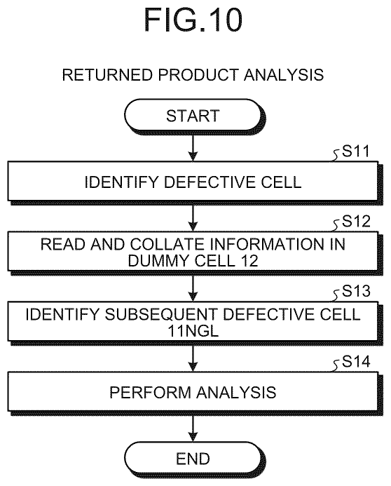

It is important to distinguish between the initial defective cell 11NG and the subsequent defective cell 11NGL for analysis of the returned semiconductor storage device 100, that is, the returned product. Using the information on the address of the initial defective cell 11NG written in the dummy cell 12 in the previous shipment test makes it possible to easily distinguish between the initial defective cell 11NG and the subsequent defective cell. This will be described with reference to FIG. 10.

FIG. 10 is a flowchart depicting an example of returned product analysis (a method for using the semiconductor storage device 100).

In Step S11, a defective cell is identified. In the same manner as in Step S1 of FIG. 8 described above, a function test using the tester 4 is performed, and the address ADD and the address IO of the defective cells are extracted. The defective cells here are all the defective cells in the normal cell array 1a, including the initial defective cell 11NG and the subsequent defective cell 11NGL.

In Step S12, the information in the dummy cell 12 is read and collated. The tester 4 accesses the dummy cell 12 via the dummy cell port 3 and reads information written in the dummy cell 12, in this example, information on the address of the initial defective cell 11NG. The tester 4 collates the information on the address of the initial defective cell 11NG read from the dummy cell 12 with the address ADD and the address IO of the defective cell extracted in Step S11 described above.

Information on the address of the subsequent defective cell 11NGL is not written in the dummy cell 12. Thus, when there is the subsequent defective cell 11NGL, collation mismatch occurs. Specifically, among the addresses ADD and the addresses IO of the defective cells identified in Step S11, the address ADD and the address IO that are not identified from the information read from the dummy cell 12 do not match in the collation.

In Step S13, the subsequent defective cell 11NGL is identified. The tester 4 identifies the subsequent defective cell 11NGL based on the information (difference information) that results in mismatch in the previous collation in Step S12. Specifically, the tester 4 identifies a defective cell identified with the address ADD and the address IO indicated by the difference information among the defective cells identified in the previous Step S11 as the subsequent defective cell 11NGL.

In Step S14, analysis is performed. For example, physical analysis or the like of the subsequent defective cell 11NGL identified in Step S13 described above is performed.

The initial defective cell 11NG and the subsequent defective cell 11NGL can be distinguished and used for analysis such as physical analysis as described above, for example.

### 2. Modification

The disclosed technology is not limited to the above embodiment. Some modifications will be described.

In the above embodiment, a case where the dummy cells 12 are arranged in the entire outer peripheral region of the normal cell array 1a has been described as an example. However, the dummy cells 12 may be arranged only in a partial region of the outer peripheral region of the normal cell array 1a.

In the above embodiment, the magnetic memory element, more specifically, a MRAM element has been described as an example of the non-volatile memory element. However, the non-volatile memory element may be various known magnetic memory elements other than the MRAM element, or may be various known non-volatile memory elements other than the magnetic memory element.

### 3. Example of Effects

The technology described above is specified as follows, for example. One of the technologies to be disclosed is the semiconductor storage device 100. As described with reference to FIG. 1 and the like, the semiconductor storage device 100 includes the normal cell array 11a including a plurality of normal cells 11, each of the plurality of normal cells 11 being a non-volatile memory cell, and a plurality of dummy cells 12 arranged in at least a partial region of an outer peripheral region of the normal cell array 11a, each of the plurality of dummy cells 12 being a non-volatile memory cell. Information on the semiconductor storage device 100 is written in at least some dummy cell 12 of the plurality of dummy cells 12.

According to the semiconductor storage device 100, the dummy cell 12 in which the information is written is arranged in an outer peripheral region of the normal cell array 1a, that is, in the same layout block (in the same memory cell array 1) as the normal cell 11. Writing information in such a dummy cell 12 makes it possible to write information without providing a non-volatile storage region such as a PROM or an OPT separately from the memory cell array 1. Thus, a decrease in area efficiency can be suppressed.

The information may include at least either information on the initial defective cell 11NG in the normal cell array 11a or information on production management of the semiconductor storage device 100. The information on the initial defective cell 11NG may include at least one of information on the number of the initial defective cells 11NG, information on an address of the initial defective cell 11NG, and information on error correction code data (ECC data) for correcting an error caused by the initial defective cell 11NG. The information on production management may include at least one of information on a vendor ID, information on a lot number, and information on a chip ID. It is possible to write various types of information on the semiconductor storage device 100 while suppressing a decrease in area efficiency (that is, efficiently write information).

As described with reference to FIGS. 3, 7 and the like, the information on the address of the initial defective cell 11NG may be written by causing the dummy cell 12 in a same row as the initial defective cell 11NG and the dummy cell 12 in a same column as the initial defective cell 11NG to have a state different from the initial state. This makes it possible to write the information on the address of the initial defective cell 11NG with the dummy cell 12 having a small number of bits. For example, for 16×16 normal cells 11, only 32 bit dummy cells 12 are sufficient.

As described with reference to FIGS. 2 and 3 and the like, the non-volatile memory cell, that is, the normal cell 11, may include the magnetic memory element 111, and the dummy cell 12 may include the magnetic memory element 121. The magnetic memory element 121 of the dummy cell 12 may be smaller than the magnetic memory element 121 of the normal cell 11 (for example, width D2<width D1). The magnetic memory element 121 includes the insulating layer 121c provided between the magnetic material layer 121a and the magnetic material layer 121b (magnetic material layers), and writing of information to the dummy cell 12 may include breaking the insulating layer 121c. Information can be held for a further long period of time, and reliability of information stored in the dummy cell 12 further improves.

As described with reference to FIG. 1 and the like, the semiconductor storage device 100 may include the dummy cell port 3 for accessing at least some dummy cell 12 from the outside (for example, the tester 4 and the system 5) of the semiconductor storage device 100. For example, information can be written to the dummy cell 12 or information can be read from the dummy cell 12 via such a dedicated port.

As described with reference to FIGS. 4 to 6 and the like, the dummy cell port 3 may be connected to the bit line BL-a of the dummy cell 12 arranged in a region outside the normal cell array 1a in the array row direction (Y-axis direction) among the plurality of dummy cells 12. It is possible to access the dummy cell 12 connected to the bit line BL-x, that is, the dummy cell 12 arranged in the bit line direction (column direction, X-axis direction).

As described with reference to FIG. 5 and the like, the semiconductor storage device 100 may include the switches 31, 33, 34, and 36 that connect the dummy cell port 3 to the bit line BL-a of the dummy cell 12 arranged in a region outside the normal cell array 1a in the array row direction (Y-axis direction) among the plurality of dummy cells 12 or to the bit line BL-B of the dummy cell 12 arranged outside the normal cell array 1a in the array column direction (X-axis direction) among the plurality of dummy cells 12. It is also possible to access the dummy cell 12 connected to the bit line BL-B, that is, the dummy cell 12 arranged in the word line direction (row direction, Y-axis direction).

As described with reference to FIG. 6 and the like, the dummy cell port 3 may be connected to the bit line BL-x of the dummy cells 12 arranged over a plurality of columns in the region outside the normal cell array 1a in the array row direction (Y-axis direction) among the plurality of dummy cells 12. It is possible to access many dummy cells 12 arranged over a plurality of columns.

The method described with reference to FIGS. 8 and 10 is also one of the technologies to be disclosed. The method is a method for using the semiconductor storage device 100 described above, the method including writing information on the semiconductor storage device 100 in at least some dummy cell 12 of the plurality of dummy cells 12 (Step S2). Using the semiconductor storage device 100 makes it possible to write information while suppressing a decrease in area efficiency (that is, efficiently write information).

The information includes information on an initial defective cell in the normal cell array 1a of the semiconductor storage device 100, and the method may include reading information from at least some dummy cell 12 of the semiconductor storage device 100 (Step S12), and identifying a subsequent defective cell 11NGL in the normal cell array 1a based on the read information (Step S13). The initial defective cell 11NG and the subsequent defective cell 11NGL can be distinguished in this manner, for example.

The effects described in the present disclosure are merely examples and are not limited to the disclosed contents. There may be other effects.

Although the above description is given regarding the embodiments of the present disclosure, the technical scope of the present disclosure is not limited to the above-described embodiments as they are, and various modifications can be made without departing from the scope of the present disclosure. In addition, the components in different embodiments and modifications may be appropriately combined.

The present technology may also take the following configurations.

(1) A semiconductor storage device comprising:
a normal cell array including a plurality of normal cells, each of the plurality of normal cells being a non-volatile memory cell; and
a plurality of dummy cells arranged in at least a partial region of an outer peripheral region of the normal cell array, each of the plurality of dummy cells being a non-volatile memory cell, wherein
information on the semiconductor storage device is written in at least some dummy cell of the plurality of dummy cells.

(2) The semiconductor storage device according to (1), wherein
the information includes at least one of information on an initial defective cell in the normal cell array and information on production management of the semiconductor storage device.

(3) The semiconductor storage device according to (2), wherein
the information on the initial defective cell includes at least one of:
information on the number of initial defective cells in the normal cell array;
information on an address of the initial defective cell in the normal cell array; and
information on error correction code data for correcting an error caused by the initial defective cell in the normal cell array.

(4) The semiconductor storage device according to (2) or (3), wherein
the information on the production management includes at least one of:
information on a vendor ID;
information on a lot number; and
information on a chip ID.

(5) The semiconductor storage device according to (3), wherein
the information on the address of the initial defective cell is written by causing the dummy cell in a same row as the initial defective cell and the dummy cell in a same column as the initial defective cell to have a state different from an initial state.

(6) The semiconductor storage device according to any one of (1) to (5), wherein
the non-volatile memory cell includes a magnetic memory element.

(7) The semiconductor storage device according to (6), wherein
the magnetic memory element of the dummy cell is smaller than the magnetic memory element of the normal cell.

(8) The semiconductor storage device according to (6) or (7), wherein
the magnetic memory element includes an insulating layer provided between magnetic material layers, and
writing the information to the dummy cell includes breaking the insulating layer.

(9) The semiconductor storage device according to any one of (1) to (8), comprising a dummy cell port for accessing the at least some dummy cell from an outside of the semiconductor storage device.

(10) The semiconductor storage device according to (9), wherein
the dummy cell port is connected to a bit line of a dummy cell among the plurality of dummy cells, the dummy cell being arranged in a region outside the normal cell array in an array row direction.

(11) The semiconductor storage device according to (9) to (10), comprising a switch that connects the dummy cell port to a bit line of a dummy cell among the plurality of dummy cells, the dummy cell arranged in a region outside the normal cell array in an array row direction, or to a bit line of a dummy cell among the plurality of dummy cells, the dummy cell being arranged outside the normal cell array in an array column direction.

(12) The semiconductor storage device according to any one of (9) to (11), wherein
the dummy cell port is connected to a bit line of dummy cells among the plurality of dummy cells, the dummy cells being arranged over a plurality of columns in a region outside the normal cell array in an array row direction.

(13) A method for using a semiconductor storage device,
the semiconductor storage device including:
a normal cell array including a plurality of normal cells, each of the plurality of normal cells being a non-volatile memory cell; and
a plurality of dummy cells arranged in at least a partial region of an outer peripheral region of the normal cell array, each of the plurality of dummy cells being a non-volatile memory cell,
the method comprising writing information on the semiconductor storage device in at least some dummy cell of the plurality of dummy cells.

(14) The method according to (13), wherein
the information includes information on an initial defective cell in the normal cell array of the semiconductor storage device, and
the method comprises:
reading the information from the at least some dummy cell of the semiconductor storage device; and
identifying a subsequent defective cell in the normal cell array based on the information that has been read.

### REFERENCE SIGNS LIST

100 SEMICONDUCTOR STORAGE DEVICE
1 MEMORY CELL ARRAY
1a NORMAL CELL ARRAY
11 NORMAL CELL
11NG INITIAL DEFECTIVE CELL
11NGL SUBSEQUENT DEFECTIVE CELL
111 MAGNETIC MEMORY ELEMENT
112 SELECTION TRANSISTOR
111a MAGNETIC MATERIAL LAYER
111b MAGNETIC MATERIAL LAYER
111c INSULATING LAYER
12 DUMMY CELL
121 MAGNETIC MEMORY ELEMENT
121a MAGNETIC MATERIAL LAYER
121b MAGNETIC MATERIAL LAYER
121c INSULATING LAYER
122 SELECTION TRANSISTOR
2 NORMAL CELL PORT
3 DUMMY CELL PORT
31 SWITCH
32 WIRING
33 SWITCH
34 SWITCH
35 WIRING
36 SWITCH
4 TESTER
5 SYSTEM
BL BIT LINE
BL-a BIT LINE
BL-β BIT LINE
WL WORD LINE
D1 WIDTH
D2 WIDTH

1. A semiconductor storage device comprising:
a normal cell array including a plurality of normal cells, each of the plurality of normal cells being a non-volatile memory cell; and
a plurality of dummy cells arranged in at least a partial region of an outer peripheral region of the normal cell array, each of the plurality of dummy cells being a non-volatile memory cell, wherein
information on the semiconductor storage device is written in at least some dummy cell of the plurality of dummy cells.

2. The semiconductor storage device according to claim 1, wherein
the information includes at least one of information on an initial defective cell in the normal cell array and information on production management of the semiconductor storage device.

3. The semiconductor storage device according to claim 2, wherein
the information on the initial defective cell includes at least one of:
information on the number of initial defective cells in the normal cell array;
information on an address of the initial defective cell in the normal cell array; and
information on error correction code data for correcting an error caused by the initial defective cell in the normal cell array.

4. The semiconductor storage device according to claim 2, wherein
the information on the production management includes at least one of:
information on a vendor ID;
information on a lot number; and
information on a chip ID.

5. The semiconductor storage device according to claim 3, wherein
the information on the address of the initial defective cell is written by causing the dummy cell in a same row as the initial defective cell and the dummy cell in a same column as the initial defective cell to have a state different from an initial state.

6. The semiconductor storage device according to claim 1, wherein
the non-volatile memory cell includes a magnetic memory element.

7. The semiconductor storage device according to claim 6, wherein
the magnetic memory element of the dummy cell is smaller than the magnetic memory element of the normal cell.

8. The semiconductor storage device according to claim 6, wherein
the magnetic memory element includes an insulating layer provided between magnetic material layers, and
writing the information to the dummy cell includes breaking the insulating layer.

9. The semiconductor storage device according to claim 1, comprising a dummy cell port for accessing the at least some dummy cell from an outside of the semiconductor storage device.

10. The semiconductor storage device according to claim 9, wherein
the dummy cell port is connected to a bit line of a dummy cell among the plurality of dummy cells, the dummy cell being arranged in a region outside the normal cell array in an array row direction.

11. The semiconductor storage device according to claim 9, comprising a switch that connects the dummy cell port to a bit line of a dummy cell among the plurality of dummy cells, the dummy cell arranged in a region outside the normal cell array in an array row direction, or to a bit line of a dummy cell among the plurality of dummy cells, the dummy cell being arranged outside the normal cell array in an array column direction.

12. The semiconductor storage device according to claim 9, wherein
the dummy cell port is connected to a bit line of dummy cells among the plurality of dummy cells, the dummy cells being arranged over a plurality of columns in a region outside the normal cell array in an array row direction.

13. A method for using a semiconductor storage device,
the semiconductor storage device including:
a normal cell array including a plurality of normal cells, each of the plurality of normal cells being a non-volatile memory cell; and
a plurality of dummy cells arranged in at least a partial region of an outer peripheral region of the normal cell array, each of the plurality of dummy cells being a non-volatile memory cell,
the method comprising writing information on the semiconductor storage device in at least some dummy cell of the plurality of dummy cells.

14. The method according to claim 13, wherein
the information includes information on an initial defective cell in the normal cell array of the semiconductor storage device, and
the method comprises:
reading the information from the at least some dummy cell of the semiconductor storage device; and
identifying a subsequent defective cell in the normal cell array based on the information that has been read.
